(19) United States
(12) Patent Application Publication
(10) Pub. No.: US 2026/0282833 A1
(43) Pub. Date: Sep. 17, 2026

(54) ELECTROSTATIC CHUCK AND SUBSTRATE FIXING DEVICE

(71) Applicant: SHINKO ELECTRIC INDUSTRIES CO., LTD., Nagano-shi (JP)

(72) Inventors: Misato Hirota, Nagano (JP); Shinichi Takimoto, Nagano (JP); Chikayoshi Yamaguchi, Nagano (JP)

(21) Appl. No.: 19/560,726

(22) Filed: Mar. 9, 2026

(30) Foreign Application Priority Data
Mar. 11, 2025 (JP) 2025-038136

(51) Int. Cl. H10P 72/72; H01J 37/32

(52) U.S. Cl. CPC H10P 72/722; H01J 37/32724; H01J 2237/2007; H01J 2237/3343

(57) ABSTRACT

An electrostatic chuck includes an adsorption part that adsorbs and holds a substrate, which is an adsorption target object, and a heating part stacked on the adsorption part. The heating part includes a first layer including a first heating body. The heating part includes a second layer stacked on the first layer and including a second heating body and a connection pattern electrically connected to the first heating body. The heating part includes a third layer stacked on the second layer and including a power supply portion electrically connected to the connection pattern. The first heating body includes a plurality of heating elements independently arranged for each of a plurality of zones. The second heating body and the connection pattern are provided on the same planar surface. An electrical resistivity of the connection pattern is lower than that of the second heating body.

### CROSS-REFERENCE TO RELATED APPLICATIONS

This application claims priority from Japanese Patent Application No. 2025-038136 filed on March 11, 2025, the contents of which are incorporated herein by reference.

### TECHNICAL FIELD

The present invention relates to an electrostatic chuck and a substrate fixing device.

### BACKGROUND ART

In the related art, a film formation apparatus and a plasma etching apparatus that are used when manufacturing a semiconductor device have a stage for accurately holding a substrate such as a silicon wafer in a vacuum treatment chamber. As such a stage, a substrate fixing device that adsorbs and holds a substrate by an electrostatic chuck mounted on a base plate is suggested (see, for example, Patent Literature 1). An electrode for adsorbing the substrate, and a heating body for controlling a temperature of the substrate are embedded in the substrate fixing device.

### CITATION LIST

### PATENT LITERATURE

Patent Literature 1: JP2020-88304A

### SUMMARY OF INVENTION

However, in the substrate fixing device described above, non-uniformity in heat-generation density may occur on a substrate placement surface of the electrostatic chuck that adsorbs the substrate. The non-uniformity in heat-generation density causes non-uniformity in temperature on the substrate. The non-uniformity in substrate temperature causes non-uniformity in etching rate in a plasma etching apparatus, for example, and thus becomes a factor that reduces the yield of semiconductor devices. Therefore, an improvement in uniformity of temperature on the substrate placement surface of the electrostatic chuck is required.

According to an aspect of the present invention, there is provided an electrostatic chuck including: an adsorption part configured to adsorb and hold an adsorption target object, and a heating part stacked on the adsorption part, in which the heating part includes a first layer including a first heating body, a second layer stacked on the first layer and including a second heating body and a connection pattern electrically connected to the first heating body, and a third layer stacked on the second layer and including a power supply portion electrically connected to the connection pattern, the first heating body includes a plurality of heating elements independently arranged for each of a plurality of zones, the second heating body and the connection pattern are provided on the same planar surface, and an electrical resistivity of the connection pattern is lower than that of the second heating body.

According to an aspect of the present invention, the uniformity of temperature on the substrate placement surface can be improved.

### BRIEF DESCRIPTION OF DRAWINGS

FIG. 1 is a schematic cross-sectional view illustrating a substrate fixing device.

FIG. 2 is a schematic cross-sectional view illustrating a first layer of a heating part.

FIG. 3 is a schematic cross-sectional view illustrating each layer of the heating part.

FIG. 4 is a graph illustrating a relationship between an alumina content ratio and an electrical resistivity.

FIG. 5 is a schematic cross-sectional view illustrating a method for manufacturing an electrostatic chuck.

FIG. 6 is a schematic cross-sectional view illustrating the method for manufacturing an electrostatic chuck.

FIG. 7 is a schematic cross-sectional view illustrating the method for manufacturing an electrostatic chuck.

FIG. 8 is a schematic cross-sectional view illustrating the method for manufacturing an electrostatic chuck.

FIG. 9 is a schematic cross-sectional view illustrating the method for manufacturing an electrostatic chuck.

### DESCRIPTION OF EMBODIMENTS

Hereinafter, one embodiment will be described with reference to the accompanying drawings.

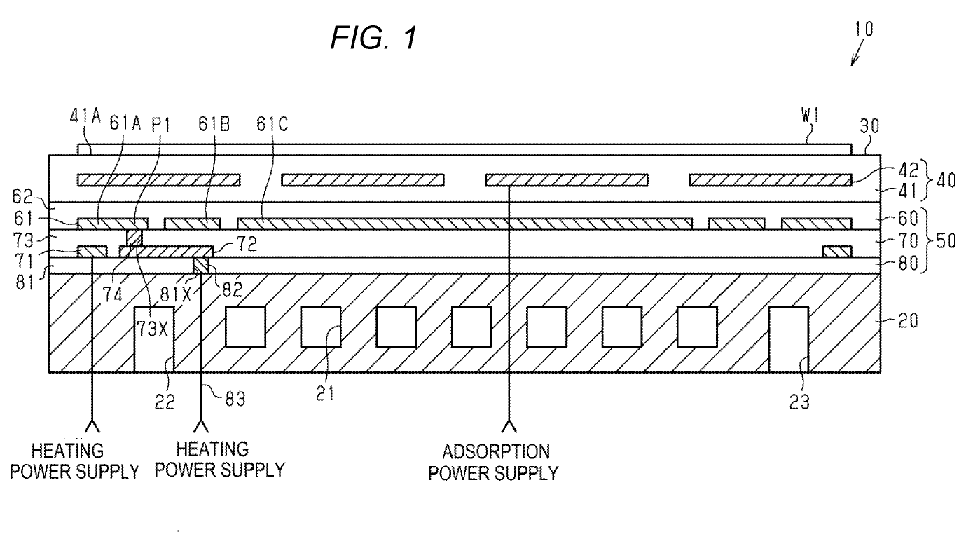

Note that, in the accompanying drawings, for the sake of convenience, a portion serving as characteristics may be shown in an enlarged manner in order to facilitate understanding of the characteristics, and a dimensional ratio of each component may be different in each drawing. In addition, in the cross-sectional drawings, in order to facilitate understanding of a sectional structure of each member, in some cases, the hatching of some members is shown by replacing the hatching with a satin-finish pattern, and in some cases, the hatching of some members is omitted. Note that, in the present specification, unless otherwise specified, a "plan view" refers to a view of an object from a vertical direction in FIG. 1 (an upper-lower direction in the drawing) and the like. In addition, unless otherwise specified, a "planar shape" refers to a shape of an object as viewed from the vertical direction in FIG. 1 and the like. Further, in the present specification, the 'upper-lower direction' and the 'left-right direction' are directions when a direction in which the reference numeral indicating each member can be correctly read in each drawing is set as the normal position. In addition, unless otherwise specified, in the description of the present disclosure, a numerical range of "X1 to X2" defined by a lower limit X1 and an upper limit X2 refers to a range of X1 or more and X2 or less.

### Overall Configuration of Substrate Fixing Device 10

As illustrated in FIG. 1, a substrate fixing device 10 includes a base plate 20 and an electrostatic chuck 30 arranged on the base plate 20. The electrostatic chuck 30 is bonded to an upper surface of the base plate 20 by an adhesive (not illustrated) such as silicone resin, for example. Note that the electrostatic chuck 30 may also be fixed to the base plate 20 by a screw. The base plate 20 is a member for mounting the electrostatic chuck 30. The electrostatic chuck 30 is a holding body that holds a substrate W1, which is an adsorption target object. The electrostatic chuck 30 is, for example, a temperature adjustment device that adjusts a temperature of the substrate W1. Note that as the substrate W1, for example, a silicon wafer may be exemplified. A diameter of the substrate W1 may be, for example, 8 inches, 12 inches, or 18 inches.

### Configuration of Base Plate 20

The base plate 20 has rigidity for supporting the electrostatic chuck 30. As materials for the base plate 20, metal materials such as aluminum and cemented carbide, and composite materials of such metal materials and ceramic materials may be used. In the present embodiment, in view of ease of availability, ease of machining, and good thermal conductivity, an aluminum or aluminum alloy having a surface subjected to anodizing is used.

A shape and a size of the base plate 20 may be formed into any shape and any size. The base plate 20 is, for example, formed in a disk shape corresponding to a shape of the substrate W1 placed on the electrostatic chuck 30. A diameter of the base plate 20 may be, for example, about 150 mm to 500 mm. A thickness of the base plate 20 may be, for example, about 10 mm to 50 mm. Here, in the present specification, the 'disk shape' refers to a planar shape having a circular shape and a predetermined thickness. Note that, in the 'disk shape', the thickness with respect to the diameter does not matter. Additionally, in the present specification, the "disk shape" also includes a shape in which a recessed portion or a protruding portion is partially formed.

In the base plate 20, for example, a cooling channel 21 is provided. The cooling channel 21 has an introduction portion 22 provided at one end and a discharge portion 23 provided at the other end. The cooling channel 21 is, for example, connected to a cooling medium control device (not illustrated) provided outside the substrate fixing device 10. The cooling medium control device introduces a cooling medium into the cooling channel 21 from the introduction portion 22 and discharges the cooling medium from the discharge portion 23. The cooling medium is circulated through the cooling channel 21 to cool the base plate 20, and thus the substrate W1 adsorbed on the electrostatic chuck 30 can be cooled. Note that as the cooling medium, for example, water or Galden may be used. In addition to the cooling channel 21, a gas channel for introducing an inert gas to cool the substrate W1 adsorbed on the electrostatic chuck 30, and the like may be provided in the base plate 20.

### Configuration of Electrostatic Chuck 30

The electrostatic chuck 30 is, for example, formed in a disk shape. A diameter of the electrostatic chuck 30 may be, for example, the same as that of the base plate 20, or may be smaller than that of the base plate 20. In the present embodiment, the diameter of the electrostatic chuck 30 is the same as that of the base plate 20. The diameter of the electrostatic chuck 30 may be, for example, about 150 mm to 300 mm. The thickness of the electrostatic chuck 30 may be, for example, about 1 mm to 10 mm.

The electrostatic chuck 30 includes an adsorption part 40 and a heating part 50. The electrostatic chuck 30 is, for example, a Johnsen-Rahbek type electrostatic chuck. Note that the electrostatic chuck 30 may also be a Coulomb-type electrostatic chuck.

### Configuration of Adsorption Part 40

The adsorption part 40 is stacked on an upper surface of the heating part 50. The adsorption part 40 includes an insulating substrate 41 and an electrostatic electrode 42.

The insulating substrate 41 has a substrate placement surface 41A (here, an upper surface) on which the substrate W1, which is an adsorption target object, is placed. A lower surface of the insulating substrate 41 is provided on an opposite side to the substrate placement surface 41A in a thickness direction of the insulating substrate 41 (the upper-lower direction in the drawing).

The insulating substrate 41 is, for example, a dielectric. As a material for the insulating substrate 41, a material with insulating properties may be used. As materials for the insulating substrate 41, ceramic materials such as aluminum oxide (Al₂O₃), aluminum nitride (AlN), and silicon nitride, and organic materials such as silicone resin and polyimide resin may be used. In the present embodiment, ceramic materials such as aluminum oxide and aluminum nitride are adopted as materials for the insulating substrate 41 in view of ease of availability, ease of machining, and relatively high resistance to plasma and the like. The insulating substrate 41 is, for example, a sintered body formed by sintering a green sheet composed of a mixture of aluminum oxide and an organic material.

Note that, in FIG. 1, the insulating substrate 41 is illustrated as a single layer, but the insulating substrate 41 may have a structure in which a plurality of insulating layers are stacked.

The electrostatic electrode 42 is an electrode for adsorbing the substrate W1. The electrostatic electrode 42 is embedded in the insulating substrate 41. The electrostatic electrode 42 is, for example, embedded in a portion located near the substrate placement surface 41A in the thickness direction of the electrostatic chuck 30. The electrostatic electrode 42 is electrically connected to an adsorption power supply provided outside the substrate fixing device 10. When a predetermined voltage is applied from the adsorption power supply, the electrostatic electrode 42 generates an adsorption force by static electricity between the electrostatic electrode and the substrate W1 placed on the substrate placement surface 41A. This makes it possible to adsorb and hold the substrate W1 on the substrate placement surface 41A. The higher the voltage applied to the electrostatic electrode 42, the stronger the adsorption holding force in the electrostatic chuck 30. The electrostatic electrode 42 may be of a unipolar shape or a bipolar shape. As a material for the electrostatic electrode 42, for example, tungsten (W) or molybdenum (Mo) may be used.

### Configuration of Heating Part 50

The heating part 50 is, for example, provided between the base plate 20 and the adsorption part 40. The heating part 50 is stacked on the upper surface of the base plate 20. Additionally, the heating part 50 is stacked on a lower surface of the adsorption part 40. The heating part 50 is, for example, formed integrally with the adsorption part 40.

The heating part 50 includes, for example, a first layer 60 stacked on the adsorption part 40, a second layer 70 stacked on the first layer 60, and a third layer 80 stacked on the second layer 70.

The first layer 60 is stacked on the lower surface of the adsorption part 40, specifically, on the lower surface of the insulating substrate 41. The first layer 60 includes a first heating body 61 and an insulating layer 62 covering the first heating body 61. The second layer 70 is stacked on a lower surface of the insulating layer 62. The second layer 70 includes a second heating body 71, a connection pattern 72, an insulating layer 73, and a via conductor 74. The third layer 80 is stacked on a lower surface of the insulating layer 73. The third layer 80 includes an insulating layer 81 and a power supply portion 82.

In the heating part 50, a substrate main body is configured by the insulating layers 62, 73, and 81. In the heating part 50, the first heating body 61, the second heating body 71, and the connection pattern 72 are embedded in the substrate main body configured by the insulating layers 62, 73, and 81.

Here, as materials for the insulating layers 62, 73, and 81, electrically insulating materials may be used. As materials for the insulating layers 62, 73, and 81, for example, materials similar to that of the insulating substrate 41 may be used. As materials for the insulating layers 62, 73, and 81, ceramic materials such as aluminum oxide, aluminum nitride, and silicon nitride, and organic materials such as silicone resin and polyimide resin may be used. The insulating layers 62, 73, and 81 of the present embodiment are sintered bodies formed by sintering a green sheet composed of a mixture of aluminum oxide and an organic material. In each drawing, an interface between the insulating substrate 41 and the insulating layer 62, an interface between the insulating layer 62 and the insulating layer 73, and an interface between the insulating layer 73 and the insulating layer 81 are indicated by solid lines. Since these interfaces are formed by stacking a plurality of green sheets, depending on the stacked state, the positions of the interfaces may differ, the interfaces may not be straight lines in a cross section, or the interfaces may be unclear.

### Configuration of First Layer 60

The first heating body 61 is for heating the substrate W1. The first heating body 61 is, for example, provided between the electrostatic electrode 42 and the lower surface of the electrostatic chuck 30 in the thickness direction of the electrostatic chuck 30. The first heating body 61 is, for example, provided on a planar surface parallel to the substrate placement surface 41A. The first heating body 61 of the present embodiment is stacked on an upper surface of the insulating layer 73. The first heating body 61 is electrically insulated from the electrostatic electrode 42. As materials for the first heating body 61, for example, copper (Cu), tungsten, nickel (Ni), and constantan (alloy of Cu/Ni/Mn/Fe) may be used. An electrical resistivity of the first heating body 61 may be, for example, about 10 μΩ·cm to 150 μΩ·cm. A thickness of the first heating body 61 may be, for example, about 10 μm to 100 μm.

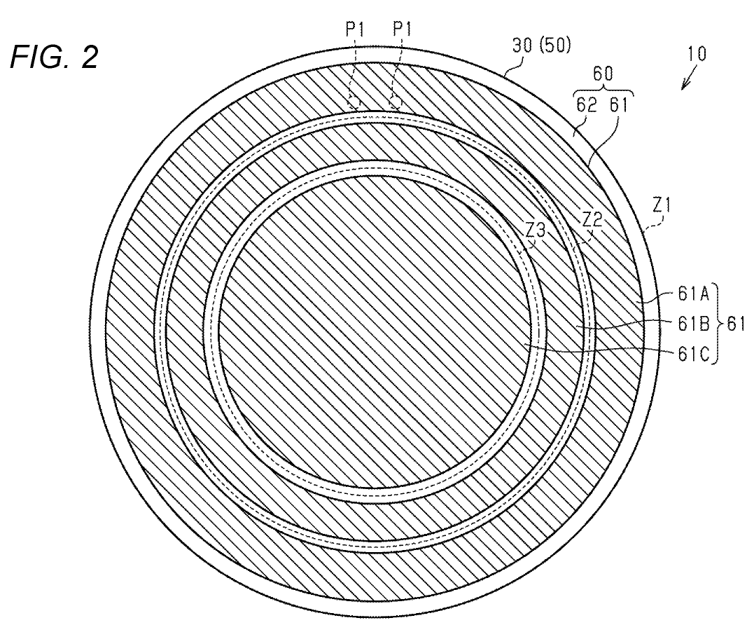

As illustrated in FIG. 2, the first heating body 61 is a multi-zone heater. The first heating body 61 includes a plurality of heating elements 61A, 61B, and 61C independently arranged for each of a plurality of regions (zones). Here, in the electrostatic chuck 30 of the present embodiment, three zones Z1, Z2, and Z3 are set concentrically in a circular shape. The zone Z1 is set on an outermost side. The zone Z2 is set on an inner side with respect to the zone Z1. The zone Z3 is set on an inner side with respect to the zone Z2.

The three heating elements 61A, 61B, and 61C are provided in three zones Z1, Z2, and Z3, respectively. The three heating elements 61A, 61B, and 61C are formed concentrically in a circular shape centered, for example, at a planar center of the electrostatic chuck 30. The three heating elements 61A, 61B, and 61C are provided on the same planar surface. The planar shape of the heating element 61A arranged in the zone Z1 is, for example, formed in an annular shape (a ring shape) surrounding the heating element 61B. The planar shape of the heating element 61B arranged in the zone Z2 is, for example, formed in an annular shape surrounding the heating element 61C. The heating element 61C arranged in the zone Z3 is, for example, formed in a circular shape.

In the first heating body 61, to make a temperature of the entire substrate W1 illustrated in FIG. 1 uniform, temperatures are individually controlled for each of the zones Z1, Z2, and Z3. Specifically, in the first heating body 61, heat generation amounts of the three heating elements 61A, 61B, and 61C are individually controlled. Here, although detailed illustration is omitted, each of the three heating elements 61A, 61B, and 61C has a single-stroke pattern. Additionally, the heating element 61A has a pair of power supply patterns P1 for electrical connection to a heating power supply provided outside the substrate fixing device 10. The pair of power supply patterns P1 is, for example, provided at both ends of the single-stroke pattern. Although illustration is omitted, the heating elements 61B and 61C each also similarly have a pair of power supply patterns P1. By independently applying voltages to the respective pairs of power supply patterns P1 of the heating elements 61A, 61B, and 61C, the respective zones Z1, Z2, and Z3 can be individually temperature-controlled.

As illustrated in FIG. 1, the insulating layer 62 is stacked on the lower surface of the insulating substrate 41. Additionally, the insulating layer 62 is stacked on the upper surface of the insulating layer 73, covering the first heating body 61. The insulating layer 62 is formed covering side and upper surfaces of the first heating body 61. Note that, in FIG. 1, the insulating layer 62 is illustrated as a single layer, but the insulating layer 62 may have a structure in which a plurality of insulating layers are stacked.

### Configuration of Second Layer 70

The insulating layer 73 is stacked on the lower surface of the insulating layer 62. The insulating layer 73 is, for example, formed covering side and upper surfaces of the second heating body 71 and side and upper surfaces of the connection pattern 72. The insulating layer 73 is, for example, formed covering a lower surface of the first heating body 61. Note that, in FIG. 1, the insulating layer 73 is illustrated as a single layer, but the insulating layer 73 may have a structure in which a plurality of insulating layers are stacked.

The via conductor 74 is formed penetrating the insulating layer 73 in the thickness direction. The via conductor 74 is, for example, formed filling a through hole 73X penetrating the insulating layer 73 in the thickness direction. The via conductor 74 is provided between the power supply pattern P1 of the first heating body 61 and the connection pattern 72. The via conductor 74 electrically connects the first heating body 61 and the connection pattern 72.

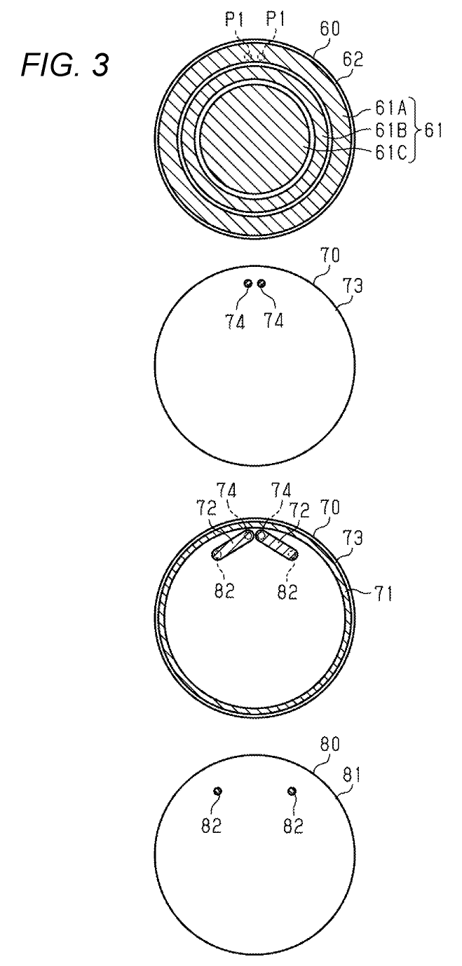

As illustrated in FIG. 3, in the second layer 70, a pair of via conductors 74 respectively connected to the pair of power supply patterns P1 is formed. Each via conductor 74 is provided overlapping each power supply pattern P1 in a plan view.

As illustrated in FIG. 1, the second heating body 71 is, for example, provided between the first heating body 61 and the lower surface of the electrostatic chuck 30 in the thickness direction of the electrostatic chuck 30. The second heating body 71 is, for example, provided on a planar surface parallel to the substrate placement surface 41A. The second heating body 71 of the present embodiment is stacked on an upper surface of the insulating layer 81. The second heating body 71 is for heating the substrate W1. The second heating body 71 is electrically insulated from the electrostatic electrode 42. The second heating body 71 is electrically insulated from the first heating body 61. As materials for the second heating body 71, for example, copper, tungsten, nickel, and constantan may be used. An electrical resistivity of the second heating body 71 may be, for example, about 10 μΩ·cm to 150 μΩ·cm. A thickness of the second heating body 71 may be, for example, about 10 μm to 100 μm.

The second heating body 71 is electrically connected to a heating power supply provided outside the substrate fixing device 10. The second heating body 71 generates heat, in response to a voltage applied from the heating power supply. The second heating body 71 heats the substrate placement surface 41A to a predetermined temperature. Note that voltages are independently applied from the heating power supply to the first heating body 61 and the second heating body 71. Accordingly, heat generation amounts of the first heating body 61 and the second heating body 71 are individually controlled.

As illustrated in FIG. 3, a planar shape of the second heating body 71 is, for example, formed in an annular shape (a ring shape). The second heating body 71 is, for example, provided in the zone Z1 (see FIG. 2). The second heating body 71 is, for example, formed overlapping a portion of the heating element 61A of the first heating body 61 in a plan view.

As illustrated in FIG. 1, the connection pattern 72 is provided on the same planar surface as the second heating body 71. The connection pattern 72 of the present embodiment is stacked on the upper surface of the insulating layer 81. The connection pattern 72 is a pattern for electrically connecting the first heating body 61 and the power supply portion 82. The connection pattern 72 extends, for example, along a plane direction (a left-right direction in the drawing) perpendicular to the thickness direction of the electrostatic chuck 30. An upper surface of a first stage of the connection pattern 72 is connected to the power supply pattern P1 of the first heating body 61 through the via conductor 74. A lower surface of a second stage of the connection pattern 72 is connected to the power supply portion 82 penetrating the insulating layer 81 in the thickness direction.

Note that, in each drawing, for the sake of simplification, only the via conductor 74, the connection pattern 72, and the power supply portion 82 connected to the heating element 61A, among the heating elements 61A, 61B, and 61C, are illustrated. However, although illustration is omitted, the heating elements 61B and 61C are also provided with similar via conductors 74, connection patterns 72, and power supply portions 82.

As illustrated in FIG. 3, in the second layer 70, a pair of connection patterns 72 respectively connected to a pair of via conductors 74 is formed. The pair of connection patterns 72 is provided spaced apart from each other. The pair of connection patterns 72 is, for example, provided on an inner side with respect to the second heating body 71 forming an annular shape, in a plan view. Each connection pattern 72 is formed overlapping the power supply pattern P1 of the heating element 61A and each via conductor 74 in a plan view, and is also formed overlapping the power supply portion 82 in a plan view. Here, the power supply portion 82 is formed not overlapping the via conductor 74 in a plan view. Each connection pattern 72 is formed extending in a plane direction between the via conductor 74 and the power supply portion 82. A planar shape of each connection pattern 72 is, for example, formed in an oblong shape.

Here, the connection pattern 72 for connecting the first heating body 61 and the power supply portion 82 does not function as a heating body for heating the substrate W1 illustrated in FIG. 1. An electrical resistivity of the connection pattern 72 is set to be lower than that of the second heating body 71. That is, the connection pattern 72 is formed of a material having a lower electrical resistivity than that of the material forming the second heating body 71. The electrical resistivity of the connection pattern 72 may be, for example, about 0.1 μΩ·cm to 10 μΩ·cm. An alumina content ratio in the connection pattern 72 is, for example, lower than that in the second heating body 71. That is, the alumina content ratio in the material forming the connection pattern 72 is lower than that in the material forming the second heating body 71. The material forming the connection pattern 72 of the present embodiment does not contain alumina.

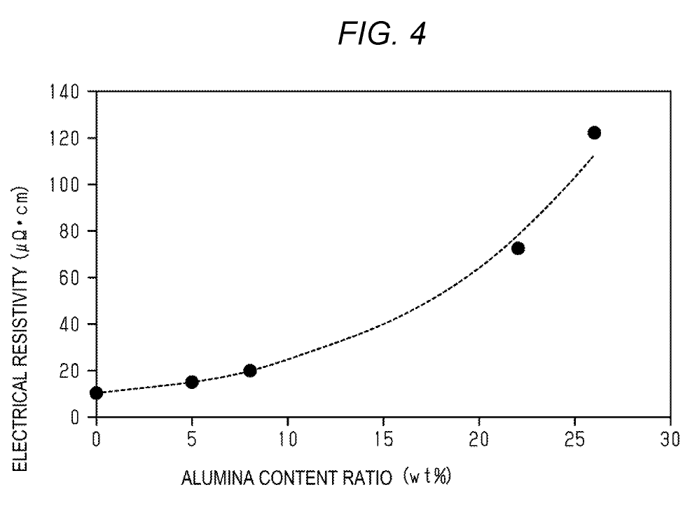

FIG. 4 is a graph illustrating a relationship between an alumina content ratio and an electrical resistivity. FIG. 4 illustrates variations in electrical resistivity when an alumina content ratio in a tungsten paste is varied. As can be clearly seen from FIG. 4, as the alumina content ratio increases, the electrical resistivity increases. Therefore, in the present embodiment, by changing the alumina content ratio, the electrical resistivity of the connection pattern 72 is set to be lower than that of the second heating body 71. Specifically, the connection pattern 72 of the present embodiment is formed by a tungsten paste that does not contain alumina. In this case, the electrical resistivity of the connection pattern 72 is about 10 μΩ·cm. In addition, the second heating body 71 of the present embodiment is formed by a tungsten paste containing 26 wt% alumina. In this case, the electrical resistivity of the second heating body 71 is about 120 μΩ·cm.

### Configuration of Third Layer 80

The insulating layer 81 is stacked on the lower surface of the insulating layer 73. The insulating layer 81 is formed covering a lower surface of the second heating body 71 and a lower surface of the connection pattern 72. A lower surface of the insulating layer 81 is, for example, bonded to the upper surface of the base plate 20 by an adhesive (not illustrated). Note that, in FIG. 1, the insulating layer 81 is illustrated as a single layer, but the insulating layer 81 may have a structure in which a plurality of insulating layers are stacked.

The power supply portion 82 is electrically connected to the connection pattern 72. The power supply portion 82 is, for example, formed filling a through hole 81X penetrating the insulating layer 81 in the thickness direction. The power supply portion 82 is, for example, electrically connected to a heating power supply via a power supply line 83. When a voltage is applied from the heating power supply to the power supply portion 82 through the power supply line 83, a voltage is applied to the first heating body 61 through the power supply portion 82, the connection pattern 72, and the via conductor 74. Then, the first heating body 61 generates heat, in response to the voltage applied from the heating power supply.

### Method for Manufacturing Electrostatic Chuck 30

Next, a method for manufacturing the electrostatic chuck 30 will be described. Here, a method for manufacturing the heating part 50 of the electrostatic chuck 30 will be described in detail.

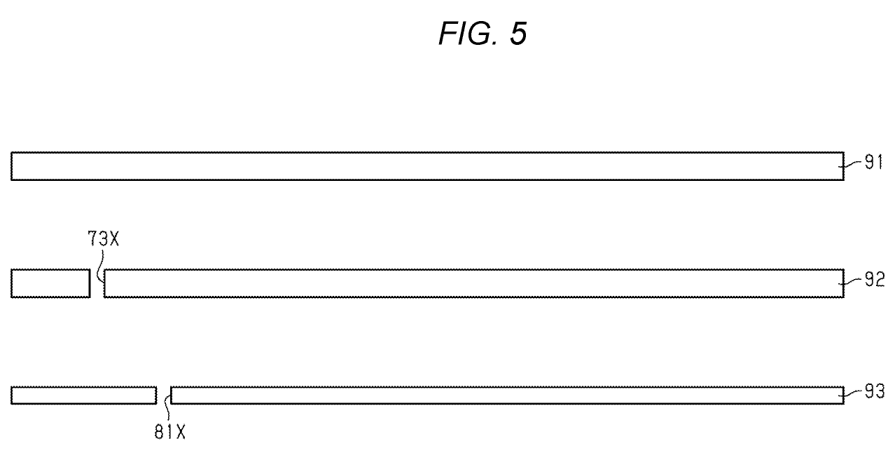

First, in a step illustrated in FIG. 5, green sheets 91, 92, and 93 composed of a ceramic material and an organic material are prepared. Each of the green sheets 91, 92, and 93 is, for example, a sheet-shaped material obtained by mixing alumina with a binder, a solvent, and the like. A size of a planar shape of each of the green sheets 91, 92, and 93 corresponds to a size of the planar shape of the heating part 50 illustrated in FIG. 1.

The green sheet 91 is fired in a step described below, thereby becoming the insulating layer 62 illustrated in FIG. 1. The green sheet 92 is fired in a step described below, thereby becoming the insulating layer 73 illustrated in FIG. 1. The green sheet 92 is provided with a through hole 73X penetrating the green sheet 92 in the thickness direction. The green sheet 93 is fired in a step described below, thereby becoming the insulating layer 81 illustrated in FIG. 1. The green sheet 93 is provided with a through-hole 81X penetrating through the green sheet 93 in the thickness direction. Note that the through holes 73X and 81X may be, for example, formed by laser processing or mechanical processing.

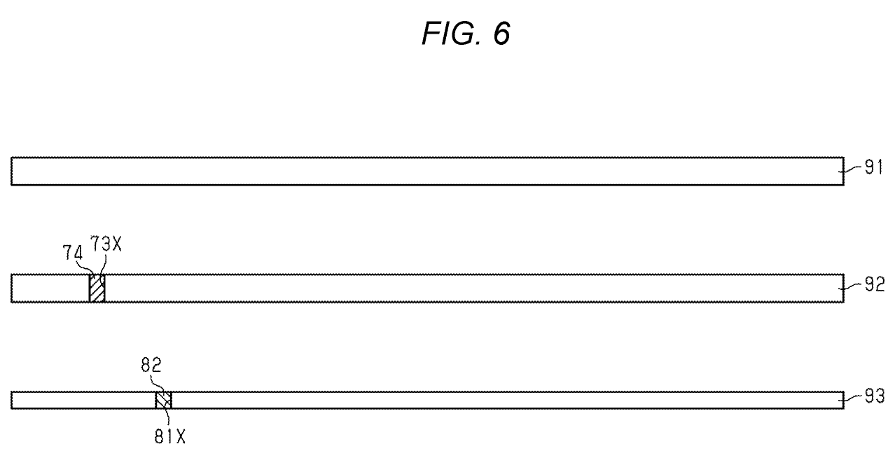

Next, in a step illustrated in FIG. 6, a conductive paste (for example, tungsten paste) is filled into the through hole 73X, thereby forming the via conductor 74 filling the through hole 73X. In addition, a conductive paste (for example, tungsten paste) is filled into the through hole 81X, thereby forming the power supply portion 82 filling the through hole 81X. The via conductor 74 and the power supply portion 82 may be, for example, formed by screen printing.

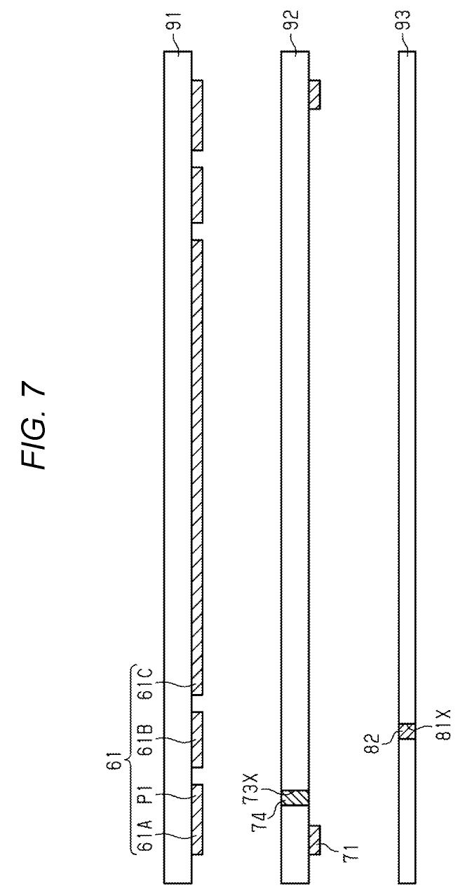

Subsequently, in a step illustrated in FIG. 7, a conductive paste (for example, a tungsten paste) is applied to a lower surface of the green sheet 91 by, for example, a screen printing method and dried, thereby forming the first heating body 61. At this time, the first heating body 61 is formed so as to have three heating elements 61A, 61B, and 61C formed concentrically in a circular shape. Additionally, the first heating body 61 is formed so as to have the power supply pattern P1 provided to overlap the via conductor 74 in a plan view. Note that the first heating body 61 may be formed on an upper surface of the green sheet 92.

Further, in the step illustrated in FIG. 7, a first conductive paste is applied to a lower surface of the green sheet 92 by, for example, a screen printing method and dried, thereby forming the second heating body 71. As the first conductive paste, a conductive paste having a composition with a high electrical resistivity may be used. For example, as the first conductive paste, a tungsten paste containing a predetermined amount of alumina (here, 26 wt%) may be used. In this step, only the second heating body 71 of the second heating body 71 and the connection pattern 72 illustrated in FIG. 1 is formed. Note that the second heating body 71 may be formed on an upper surface of the green sheet 93.

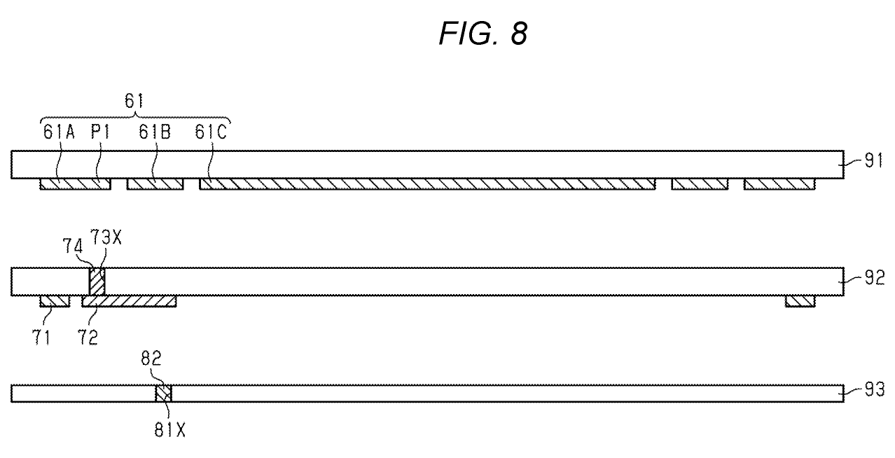

Next, in a step illustrated in FIG. 8, a second conductive paste is applied to the lower surface of the green sheet 92 by, for example, a screen printing method and dried, thereby forming the connection pattern 72. As the second conductive paste, for example, a conductive paste having a composition with a lower electrical resistivity than that of the first conductive paste may be used. For example, as the second conductive paste, a tungsten paste not containing alumina may be used. The connection pattern 72 is formed so as to overlap the via conductor 74 in a plan view, and is also formed so as to overlap the power supply portion 82 in a plan view. Note that the connection pattern 72 may be formed on the upper surface of the green sheet 93.

As described above, the second heating body 71 is first formed using the first conductive paste on the lower surface of the green sheet 92. Then, on the lower surface of the green sheet 92, the connection pattern 72 is formed using the second conductive paste having a composition with a lower electrical resistivity than that of the first conductive paste. In this manner, the second heating body 71 and the connection pattern 72 having different electrical resistivities can be formed on the same planar surface.

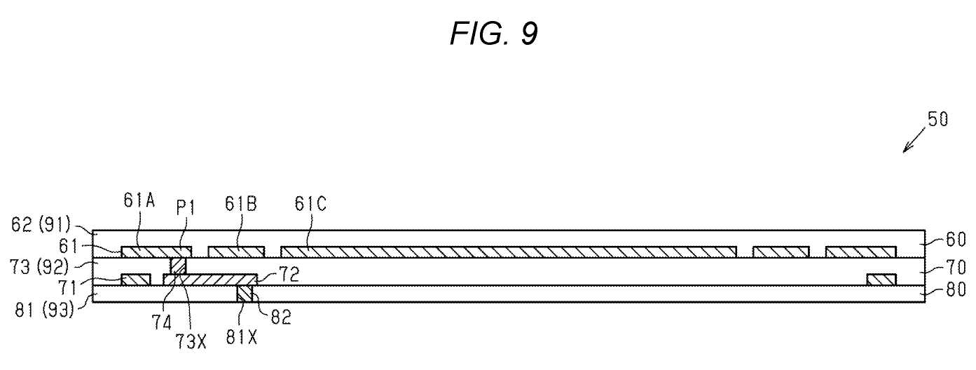

Next, in a step illustrated in FIG. 9, the green sheet 92 and the green sheet 91 are sequentially stacked on the green sheet 93. The green sheets 91, 92 and 93 are joined to each other, for example, by pressurizing the green sheets while heating the same.

Next, the structure in which the green sheets 91, 92, and 93 are stacked is fired. As a result, the green sheets 91, 92, and 93 are sintered, thereby obtaining the insulating layers 62, 73, and 81, respectively. Then, the heating part 50 can be manufactured in which the first layer 60 including the first heating body 61 and the insulating layer 62, the second layer 70 including the second heating body 71, the connection pattern 72, the insulating layer 73, and the via conductor 74, and the third layer 80 including the insulating layer 81 and the power supply portion 82 are sequentially stacked. Note that although the description is omitted herein, the adsorption part 40 illustrated in FIG. 1 may also be formed together with the heating part 50.

Note that in the present embodiment, the green sheet 91 is an example of the first green sheet, and the green sheet 92 is an example of the second green sheet.

### Operational Effects of Present Embodiment

Subsequently, operational effects of the present embodiment are described.

(1) The second heating body 71 and the connection pattern 72 are provided on the same planar surface. Here, the connection pattern 72 is for connecting the first heating body 61 and the power supply portion 82, and does not function as a heating body for heating the substrate W1. If the electrical resistivity of the connection pattern 72 is set to be equal to that of the second heating body 71 functioning as a heating body, the connection pattern 72 generates heat to the same extent as the second heating body 71. The heat generation of the connection pattern 72 may cause a non-uniformity in temperature on the substrate placement surface 41A.

In contrast, in the electrostatic chuck 30 of the present embodiment, the electrical resistivity of the connection pattern 72 is set to be lower than that of the second heating body 71. Accordingly, when a voltage is applied to the connection pattern 72, heat generation of the connection pattern 72 can be suitably suppressed. Therefore, an unintended temperature increase in a partial region on the substrate placement surface 41A caused by heat generation of the connection pattern 72 can be suppressed, and temperature non-uniformity on the substrate placement surface 41A can be suitably suppressed. As a result, the uniformity of temperature on the substrate placement surface 41A can be improved.

(2) The alumina content ratio in the material forming the connection pattern 72 is set to be lower than that in the material forming the second heating body 71. According to this configuration, by adjusting the alumina content ratio, the electrical resistivity of the connection pattern 72 can be easily adjusted to be lower than that of the second heating body 71.

(3) The material forming the connection pattern 72 of the present embodiment does not contain alumina. According to this configuration, the electrical resistivity of the connection pattern 72 can be set lower. Accordingly, when a voltage is applied to the connection pattern 72, heat generation of the connection pattern 72 can be more suitably suppressed.

### Modified Embodiments

The above embodiment can be modified and implemented as follows. The above embodiment and the following modified embodiments can be implemented in combination with each other within a technically consistent range.

The structure of the connection pattern 72 in the above embodiment can be appropriately modified. For example, the planar shape of the connection pattern 72 can be formed into any shape and any size. For example, the planar shape of the connection pattern 72 may be formed in a rectangular shape or an L-shape.

The structure of the second heating body 71 in the above embodiment can be appropriately modified. For example, the planar shape of the second heating body 71 can be formed into any shape and any size. For example, the planar shape of the second heating body 71 may be formed in a rectangular frame shape.

In the above embodiment, the second heating body 71 is formed to partially overlap the heating element 61A in a plan view, but the position at which the second heating body 71 is formed is not limited thereto. For example, the second heating body 71 may be formed to partially overlap the heating element 61C in a plan view.

In the above embodiment, the connection pattern 72 is provided on the inner side with respect to the second heating body 71 having an annular shape. However, no such limitation is intended. For example, the connection pattern 72 may be provided on an outer side with respect to the second heating body 71.

The structure of the first heating body 61 in the above embodiment can be appropriately modified.

In the above embodiment, the three heating elements 61A, 61B, and 61C are formed concentrically in a circular shape. However, for example, the three heating elements 61A, 61B, and 61C may be formed concentrically in a rectangular shape.

In the above embodiment, the first heating body 61 has a structure including three heating elements 61A, 61B, and 61C. However, the number of heating elements included in the first heating body 61 is not particularly limited. For example, the number of heating elements included in the first heating body 61 may be 2 or 4 or more.

In the above embodiment, the number of layers of the insulating layers 62, 73, and 81 in the heating part 50 is not particularly limited.

In the above embodiment, the number and shape of the zones Z1, Z2, and Z3 in the electrostatic chuck 30 are not particularly limited. For example, the zones Z1, Z2, and Z3 in the electrostatic chuck 30 may be set concentrically in a rectangular shape. For example, the number of zones in the electrostatic chuck 30 may be 2 or 4 or more.

In the above embodiment, after the second heating body 71 is formed on the lower surface of the green sheet 92, the connection pattern 72 is formed. However, no such limitation is intended. For example, after the connection pattern 72 is formed on the lower surface of the green sheet 92, the second heating body 71 may be formed.

In the above embodiment, the first heating body 61 is formed on the lower surface of the green sheet 91, and the second heating body 71 and the connection pattern 72 are formed on the lower surface of the green sheet 92. However, no such limitation is intended. For example, the first heating body 61 may be formed on the upper surface of the green sheet 92, and the second heating body 71 and the connection pattern 72 may be formed on the lower surface of the green sheet 92.

An embossed structure may be provided on the substrate placement surface 41A of the electrostatic chuck 30 of the above embodiment.

The structure of the base plate 20 of the above embodiment is not particularly limited. For example, the shape of the cooling channel 21 is not particularly limited.

The substrate fixing device 10 in the above embodiment is applied to a semiconductor manufacturing apparatus, such as a dry etching apparatus. Examples of the dry etching apparatus include a parallel flat plate type reactive ion etching apparatus. Further, the substrate fixing device 10 can also be applied to a semiconductor manufacturing apparatus such as a plasma CVD (Chemical Vapor Deposition) apparatus and a sputtering apparatus.

This disclosure further encompasses various exemplary embodiments, for example, described below.

1. A method for manufacturing an electrostatic chuck comprising an adsorption part configured to adsorb and hold an adsorption target object and a heating part stacked on the adsorption part, the method comprising:

preparing a first green sheet and a second green sheet;

forming a first heating body on a lower surface of the first green sheet;

forming a through hole penetrating the second green sheet in a thickness direction;

forming a via conductor filling the through hole so as to overlap the first heating body in a plan view;

forming a second heating body on a lower surface of the second green sheet so as not to overlap the via conductor in a plan view;

forming, on the lower surface of the second green sheet, a connection pattern having a lower electrical resistivity than that of the second heating body so as to be connected to the via conductor;

stacking the first green sheet on an upper surface of the second green sheet; and

firing the first green sheet and the second green sheet stacked on each other.

What is claimed is:

1. An electrostatic chuck comprising:
an adsorption part configured to adsorb and hold an adsorption target object; and
a heating part stacked on the adsorption part, wherein
the heating part comprises
a first layer comprising a first heating body,
a second layer stacked on the first layer and comprising a second heating body and a connection pattern electrically connected to the first heating body, and
a third layer stacked on the second layer and comprising a power supply portion electrically connected to the connection pattern,
the first heating body comprises a plurality of heating elements independently arranged for each of a plurality of zones,
the second heating body and the connection pattern are provided on the same planar surface, and
an electrical resistivity of the connection pattern is lower than that of the second heating body.

2. The electrostatic chuck according to claim 1, wherein an alumina content ratio in a material forming the connection pattern is lower than that in a material forming the second heating body.

3. The electrostatic chuck according to claim 2, wherein the material forming the connection pattern does not contain alumina.

4. The electrostatic chuck according to claim 1, wherein a planar shape of the second heating body is formed in an annular shape, and
the connection pattern is provided on an inner side with respect to the second heating body in a plan view.

5. The electrostatic chuck according to claim 1, wherein the plurality of heating elements are formed concentrically in a circular shape on the same planar surface, and
the connection pattern is electrically connected to the first heating body through a via conductor provided between the first heating body and the connection pattern.

6. A substrate fixing device comprising:
the electrostatic chuck according to claim 1; and
a base plate joined to the electrostatic chuck.
